(19) United States
(12) Patent Application Publication
(10) Pub. No.: US 2020/0292608 A1
(43) Pub. Date: Sep. 17, 2020

(54) RESIDUAL-BASED SUBSTATION CONDITION MONITORING AND FAULT DIAGNOSIS

(71) Applicant: General Electric Company, Schenectady, NY (US)

(72) Inventors: Weizhong YAN, Clifton Park, NY (US); Honggang WANG, Clifton Park, NY (US); Lijun HE, Schenectady, NY (US)

(21) Appl. No.: 16/562,711

(22) Filed: Sep. 6, 2019

Related U.S. Application Data
(60) Provisional application No. 62/817,956, filed on Mar. 13, 2019.

(51) Int. Cl. G01R 31/08; G06N 20/00; G01R 19/25

(52) U.S. Cl. CPC G01R 31/086; G01R 19/2513; G06N 20/00

(57) ABSTRACT

Briefly, embodiments are directed to a system, method, and article for monitoring and diagnosing a status of one or more assets of a power grid system. Input data measurements and training data measurements from one or more data sources relating to the power grid system may be accessed or received. An offline training phase and an online monitoring and diagnosis phase may be performed. During the offline training phase, first features may be extracted from the training measurement data, one or more residual generation models may be trained using the extracted features as model inputs, and one or more residual-based classifiers may be trained. During the online monitoring and diagnosis phase, second features may be extracted from the input measurement data, one or more residuals may be generated based on the extracted second features, and a status of the one or more assets may be determined based on the one or more residuals, where the one or more residuals may comprise a difference between model predicted values and measured values from the one or more data sources. An output may be generated indicating the status of the one or more assets based on the classification of the status.

### CROSS-REFERENCE TO RELATED APPLICATIONS

The present application claims the benefit of U.S. Provisional Patent Application No. 62/817,956 entitled “EXTREMELY FAST SUBSTATION ASSET MONITORING” and filed on Mar. 13, 2019. The entire content of that application is incorporated herein by reference.

### BACKGROUND

A power grid or electrical grid is an interconnected network for delivering electricity from producers to consumers. A power grid typically contains various pieces of equipment or assets. For example, a power system may include one or more generators, one or more substations, power transmission lines, and power distribution lines. A generator or generating station may generate electric power from sources of primary energy or may convert motive power into electrical power for transmission to a power electrical grid. A substation may be a part of an electrical generation, transmission, and distribution system. Between a generating station and consumer, electric power may flow through several substations at different voltage levels. A substation may include transformers to change voltage levels between high transmission voltages and lower distribution voltages, or at the interconnection of two different transmission voltages. Electric power transmission lines may facilitate bulk movement of electrical energy from a generating site, such as a power plant comprising one or more generators, to one or more electrical substations. The interconnected lines which facilitate this movement are known as a transmission network.

Substations typically contain or are otherwise dependent upon a number of critical assets. These assets include items such as power transformers, Current transformers, Potential transformers, circuit breakers, protective relays, insulators, Intelligent Electronic Devices (LEDs), Lightening arresters, capacitor banks, and underground cables, to name but a few. The aging infrastructure spread across large territories becomes a challenge for the grid reliability and power availability. For example, some reports indicate that approximately 50% of customer-minutes lost may be attributed to equipment failure. Optimizing the maintenance, repair, and replacement of these and other assets may be a challenging task, particularly when viewed in the larger context of system reliability.

Critical assets such as power transformers may be monitored online with additional instruments, such as dissolved gas analysis (DGA) sensors, partial discharge (PD) monitor sensors, moisture sensors at various locations of the equipment like main oil tank, on-load tap changer (OLTC), and bushing. However, the installation of additional sensors adds extra cost and complexity to the system, as well as new reliability challenge, for example DGA sensors need replacement every 5-10 years. For uncritical assets there is less/no sensor installed that can help with online monitoring the asset healthy condition. Instead, onsite field inspection is always required, and unplanned maintenance causes unnecessary downtime and extra repair cost.

### SUMMARY

According to an aspect of an example embodiment, a system for monitoring and diagnosing a status of one or more assets of a power grid system may be provided. Input data measurements and training data measurements from one or more data sources relating to the power grid system may be accessed or received. An offline training phase and an online monitoring and diagnosis phase may be performed. During the offline training phase, first features may be extracted from the training measurement data, one or more residual generation models may be trained using the extracted features as model inputs, and one or more residual-based classifiers may be trained. During the online monitoring and diagnosis phase, second features may be extracted from the input measurement data, one or more residuals may be generated based on the extracted second features, and a status of the one or more assets may be determined based on the one or more residuals, where the one or more residuals may comprise a difference between model predicted values and measured values from the one or more data sources. An output may be generated indicating the status of the one or more assets based on the classification of the status.

According to an aspect of another example embodiment, a method for monitoring and diagnosing a status of one or more assets of a power grid system may be provided. Input data measurements and training data measurements from one or more data sources relating to the power grid system may be accessed or received. An offline training phase and an online monitoring and diagnosis phase may be performed. During the offline training phase, first features may be extracted from the training measurement data, one or more residual generation models may be trained using the extracted features as model inputs, and one or more residual-based classifiers may be trained. During the online monitoring and diagnosis phase, second features may be extracted from the input measurement data, one or more residuals may be generated based on the extracted second features, and a status of the one or more assets may be determined based on the one or more residuals, where the one or more residuals may comprise a difference between model predicted values and measured values from the one or more data sources. An output may be generated indicating the status of the one or more assets based on the classification of the status.

According to an aspect of another example embodiment, an article may comprise a non-transitory storage medium comprising machine-readable instructions executable by one or more processors. The instructions may be executable by the one or more processors to access input data measurements and training data measurements from one or more data sources relating to the power grid system. The instructions may be executable by the one or more processors to implement an offline training phase and an online monitoring and diagnosis phase. During the offline training phase, first features may be extracted from the training measurement data, one or more residual generation models may be trained using the extracted features as model inputs, and one or more residual-based classifiers may be trained. During the online monitoring and diagnosis phase, second features may be extracted from the input measurement data, one or more residuals may be generated based on the extracted second features, and a status of the one or more assets may be determined based on the one or more residuals, where the one or more residuals may comprise a difference between model predicted values and measured values from the one or more data sources. The instructions may be further executable by the one or more processors to generate an output indicating the status of the one or more assets based on the classification of the status.

Other features and aspects may be apparent from the following detailed description taken in conjunction with the drawings and the claims.

### BRIEF DESCRIPTION OF THE DRAWINGS

Features and advantages of the example embodiments, and the manner in which the same are accomplished, will become more readily apparent with reference to the following detailed description taken in conjunction with the accompanying drawings.

FIG. 1 illustrates an embodiment of a power distribution grid.

FIG. 2 is a functional block diagram of an embodiment of a Residual-Based Event Diagnosis System (RBEDS) according to an embodiment.

FIGS. 3A and 3B illustrate features, feature vectors, and decision boundaries in accordance with some embodiments.

FIG. 4 is a schematic view of a decision boundary separating abnormal data from normal data set with region containing incomplete training data in accordance with some embodiments.

FIG. 5 illustrates a system that may create stateful, nonlinear embedding in accordance with some embodiments.

FIG. 6 illustrates a method to create stateful, nonlinear embedding in accordance with some embodiments.

FIG. 7 illustrates an abnormality detection system for an industrial asset in accordance with some embodiments.

FIG. 8 illustrates an embodiment a system diagram of a RBEDS and corresponding inputs and outputs according to an embodiment.

FIG. 9 illustrates an embodiment of a process for performing residual-based event diagnosis.

FIG. 10 is a feature vector information flow diagram in accordance with some embodiments.

FIG. 11 illustrates layers of an autoencoder algorithm in accordance with some embodiments.

FIG. 12 is a neural network model structure for function θ₁ in accordance with an example embodiment.

FIG. 13 illustrates an embodiment of a multi-scale convolutional neural network.

FIG. 14 illustrates a power grid system including an RBEDS module in accordance with an example embodiment.

FIG. 15 illustrates an RBEDS server according to an embodiment.

Throughout the drawings and the detailed description, unless otherwise described, the same drawing reference numerals will be understood to refer to the same elements, features, and structures. The relative size and depiction of these elements may be exaggerated or adjusted for clarity, illustration, and/or convenience.

### DETAILED DESCRIPTION

In the following description, specific details are set forth in order to provide a thorough understanding of the various example embodiments. It should be appreciated that various modifications to the embodiments will be readily apparent to those skilled in the art, and the generic principles defined herein may be applied to other embodiments and applications without departing from the spirit and scope of the disclosure. Moreover, in the following description, numerous details are set forth for the purpose of explanation. However, one of ordinary skill in the art should understand that embodiments may be practiced without the use of these specific details. In other instances, well-known structures and processes are not shown or described in order not to obscure the description with unnecessary detail. Thus, the present disclosure is not intended to be limited to the embodiments shown but is to be accorded the widest scope consistent with the principles and features disclosed herein.

One or more embodiments, as discussed herein, generally comprise a power and substation monitoring system. For example, the monitoring of the state of substation assets may be performed in accordance with an embodiment at a subsecond rate, such that early warning indications may be provided for potentially malfunctioning equipment, and equipment may be proactively replaced and/or repaired before the equipment becomes damaged. Accordingly, an electric utility's incidence of forced outage of equipment and capital replacement costs may be reduced, and catastrophic failures and collateral damage may thereby be avoided. In one aspect, a Phasor Measurement Units (PMU) application may be extended to substation asset monitoring, for example.

A “Phasor Measurement Unit” or “PMU,” as used herein, refers to a device used to estimate the magnitude and phase angle of an electrical phasor quantity (such as voltage or current) in a power grid using a common time source for synchronization. Time synchronization may be provided by Global Positioning System (GPS) coordinates and may allow for synchronized real-time measurements of multiple remote points on an electricity grid. PMUs may be capable of capturing samples from a waveform in quick succession and reconstructing a phasor quantity, made up of an angle measurement and a magnitude measurement, for example. A resulting measurement is known as a “synchrophasor.” Such time synchronized measurements may be monitored, for example, because if a power grid's supply and demand are not perfectly matched, frequency imbalances may cause stress on the power grid, potentially resulting in power outages.

PMUs may also be used to measure a frequency in a power grid. A typical commercial PMU may report measurements with very high temporal resolution in the order of 30-60 measurements per second, for example. Such measurements may assist engineers in analyzing dynamic events in the power grid which may not be possible with traditional Supervisory Control and Data Acquisition (SCADA) measurements which generate one measurement every 2 or 4 seconds. PMUs may therefore equip utilities with enhanced monitoring and control capabilities and are considered to be one of important measuring devices in the future of power systems. A system may include one or more receivers or transceivers, for example, to receive signals comprising measurements or parameters from one or more PMUs.

In accordance with one or more embodiments, a machine learning-based power substation asset monitoring system is provided. For example, such a machine learning-based power substation asset monitoring system may receive and process data from various sources, such as a PMU data, SCADA data, and other various operational and non-operational information and may output a probability set, each element of which may represent a likelihood that an event observed has been triggered by a failure mode of each of the substation subsystems and components. Such a system may include components to perform operations such as feature extraction, residual generation, and residual-based classification, as discussed in more detail below. Features may comprise individual quantities extracted from one or more measured data streams.

A power substation asset monitoring system in accordance with one or more embodiments, as discussed herein, may comprise an offline analysis module which may acquire training data from different sources. The system may process the training data, extract features from the training data, generate one or multiple residual generation models based on the extracted features, and generate one or multiple classifiers for an online anomaly detection and fault diagnosis module. An online anomaly detection and fault diagnosis module may receive power system-related data from field devices, may generate state of substation system and component and an unclassified state.

Existing substation monitoring processing may take multiple seconds or minutes to be performed. For example, such existing systems do not fully utilize PMU data. In a traditional anomaly and fault diagnosis system, detection and localization typically occurs in serial, thereby imposing delays in the localization. Electric power systems, however, exhibit very fast dynamics which may require abnormal detection and localization to also occur relatively quickly.

Studies show that approximately 50% of customer-minutes lost may be attributed to equipment failure. Installation of a sensor such as Dissolved Gas Analysis (DGA) and/or Partial Discharge (PD) may introduce additional costs and complexity to a system, as well as new reliability challenges. PMU data may be measured at 30˜120 sample/sec and may be Global Positioning System (GPS) synchronized. However, such data has not been fully explored or used for asset monitoring. For equipment failure, PMU-captured data for a substation has been primarily analyzed in a post-event fashion, using an engineer's judgment. A drawback is this process is lack of consistent and systematic reasoning for system diagnosis, and the troubleshooting process with human in the loop is time consuming which may miss the “critical time duration” to avoid a more severe failure or explosion.

An asset monitoring system may be improved in accordance with an embodiment, for example, to provide an automatic solution (e.g., software) to correlate PMU captured event data to determine a status of an asset or equipment. PMU data may be analyzed to provide a relatively fast diagnosis (e.g., at a subsecond level) to avoid more severe equipment failure or explosion, for example.

A systematic approach is provided in accordance with an embodiment as discussed herein to unleash the power of the big volume of PMU data together with operational and non-operational data, along with the help of advanced artificial intelligence (AI) and/or machine learning (ML) technology for asset monitoring and diagnosis, for example.

An embodiment, as discussed herein, may perform anomaly detection and may also provide anomaly localization to a component level. Moreover, a machine learning-based approach may include intelligence such as a “self-healing” model update, for example. Substation assets may be monitored approximately in real-time with a PMU streaming time series analysis, for example. A collection of ensembles may be combined with data augmentation for enhanced classification accuracy under a small sample size and unbalanced data challenge. An embodiment may provide an automatic model update triggered, for example, by a certified public resource event and an operator-acknowledged event with label.

Relatively few labeled data (such as PMU data) may currently be available because PMU installations have only recently been performed. A traditional deep learning approach may suffer from overfitting or poor generalization performance with a relatively small sample size data and unbalanced data (e.g., a lot of normal data but very few data for a certain anomaly). A data source may be extended from not only a simulator, but also from an equipment failure mode data sheet and publicly available PMU related asset data, for example. Furthermore, a data augmentation approach augmentation may be utilized such as Jittering, boostrapping, and generative modeling, to name just a few examples, to enhance the classifier's prediction accuracy and generalization capability. Ensembles of different similarity metrics, time and frequency transformations, single component and multiple component interaction features may additionally be leveraged to further enhance a classifier's accuracy, for example.

Use of PMU data for substation asset state monitoring is at a relatively early stage and no machine learning model may be capable of handling all possible scenarios or events. A scheme is therefore provided in accordance with one or more embodiments so as to allow a model to automatically update. Automatic updating may be performed by proper design of model output and a model performance monitoring module, for example. First, there may be an “unclassified class” as a classifier model output, which is true if an incoming subsequent time series does not belong to any of a normal or predefined anomaly class. For each unclassified instance, for example, a counter in a model performance module may increase by a value of “one.” Meanwhile, a time series may be saved in a temporal database. To enable interactive learning from the operator, for example, a model performance module may also issue an alert to a user interface in a control center. Once a number of unclassified instances reach to a certain threshold number, such as 20, for example, the system may trigger a low-level alarm once to allow for an operator to analyze stored time series snapshots and confirm a particular data label. Subsequent labeled data may be sent to a classifier database for model training use. This automatic model update with learning capability from human may make the system adaptable to system change caused by reconfiguration, retrofit and/or device replacement, for example.

With the proliferation of PMU installations, synchrophasor technology offers unprecedented visibility into what is happening on the grid as a whole, and into what is happening with individual power plants and pieces of grid equipment. Synchrophasor systems enable better electric system observation and problem diagnosis because synchrophasor technology synchronously samples and records grid conditions with unprecedented speed and granularity. While SCADA systems sample grid conditions every 2 to 15 seconds, PMUs measure frequency, voltage phasors, and current phasors at the rate of 30 to 120 samples per second and calculate real and reactive power values from those phasor measurements. Thus, PMUs can capture dynamic and transient events that are not seen in SCADA monitoring. Every phasor measurement and calculated value is time-synchronized against Universal Time (within 1 microsecond, as determined using GPS), producing accurate, time-aligned measurements that may be compared and tracked across wide geographic areas. This makes it easier to correctly identify and diagnose events occurring across a large region.

One or more embodiments may provide a software solution to facilitate PMU based asset monitoring. For example, one or more embodiments may provide an automatic solution (software) to correlate a PMU captured event with an asset status. One of more embodiments may also provide a systematic approach to unleash a big volume of PMU data together with other related large volumes operational and non-operational data, and the power of advanced Artificial Intelligence (AI)/Machine Learning (ML) technology for asset monitoring and diagnosis.

Various assets and related monitoring equipment may generate large volumes operational and non-operational data. Examples of operational data include information such as voltage, current, breaker status, and other information which may be used to monitor and control operation of a substation and other elements of the transmission and distribution system on a substantially real time basis. Example of non-operational data include analytical data (e.g., digital fault records target records, load profiles, power quality, sequence of events, and the like), equipment condition information (e.g., equipment temperature, dissolved gasses, operating and response times, and so on), and temperature, rainfall, and other ambient condition information. Both operational and non-operational data may have relatively substantial value for monitoring and analyzing the operation of a particular asset.

Accordingly, a related software solution as discussed herein may provide various benefits, such as enabling or facilitating PMU based asset monitoring. In one embodiment, as discussed below, an automatic solution (e.g., software) may correlate a PMU-captured event to determine a status of an asset.

Given an event captured by PMU data or other types of data such as SCADA, for example, one or more embodiments as discussed herein may be able to determine whether the event signifies the failure, degradation or malfunction of instrument transformer, or power transformer or other components such as circuit breaker, etc.

One or more embodiments, as discussed herein, may address various technical challenges. First, there is a lack of knowledge base to correlate PMU data effect and the asset failure mode. Even though failure modes for instruments (e.g., CT, VT, CCVT) and equipment (e.g., Power Xfmr, Bushing, Circuit Breaker) are well-established, their behavior in the sub-second level has not been fully understood. The activity of correlating PMU data to asset failure has only recently begun and little or nothing is known about a correlation between PMU and rarely occurring asset failures.

A second technical challenge is that there is a lack of PMU dataset which correlates PMU data effect and an asset failure mode. Asset owners may not publicly share their assets failures and corresponding PMU data may differ for different asset owners. Each asset owner may have only a few event histories with equipment failure.

A third technical challenge is that it is not straightforward to align PMU data with other source data, which may include SCADA data, state estimator data, messaging data, alarm data and/or static data (e.g., network topology, line impedance loads).

A fourth technical challenge is that for a certain PMU events (e.g., signatures), there may be multiple failure modes corresponding to them due to the limitations of PMU installation locations and available measurement channels.

A fifth technical challenge is that a PMU based event detection and diagnosis be as fast as possible or (sub-second level) be able to take remedy actions for certain failures, such as s bushing failure.

Another way to update a model in accordance with an embodiment by actively searching for PMU related asset condition data from publicly available resources, such as industry literature, event logs, outage reports, to name just a few examples. Once such new available data reaches a certain value, for example, a similarity between a new instance and existing training examples or instances may be determined. If a highest similarity index value falls below a predefined threshold, then this newly detected instance may be added to the training data or instances and a new model may be initiated, for example.

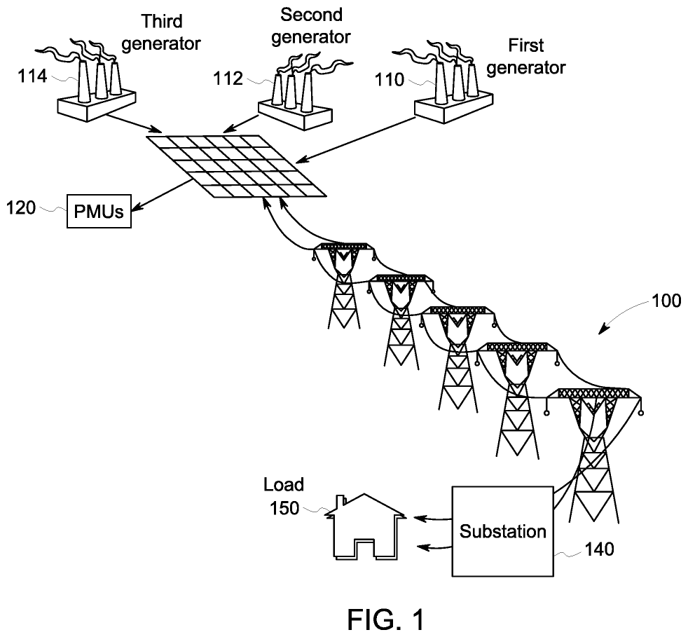

FIG. 1 illustrates an embodiment 100 of a power distribution grid. The grid of embodiment 100 may include a number of components, such as one or more power generators, for example, a first generator 110, second generator 112, and/or third generator 114. Although only three generators are shown in FIG. 1, it should be appreciated that more or fewer than three generators may be utilized in accordance with an embodiment. The grid of embodiment 100 may include transmission networks, transmitting electrons from power generator to one or more substations, such as substation 140, and distribution networks to various loads or users. In embodiment 100, for example, electrons may be transmitted from substation 140 to various loads, such as load 150. Although only a single substation 140 is illustrated in FIG. 1, it should be appreciated that numerous substations may be included in some embodiments, such as where electric power is transmitted from one or more generators to different geographically dispersed loads, for example. Similarly, although only a single load 150 is illustrated in FIG. 1, multiple loads may be included in some embodiments, where the multiple loads draw power from the power distribution grid in accordance with an embodiment.

There are numerous assets located within or along the power distribution grid, between one or more generators, such as first generator 110, and load 150. An “asset” or “electrical asset,” as used herein, refers to an item, such as one or more components of equipment, involved in generation and/or transmission of electrical power between one or more generators and one or more loads or consumers of the electrical power. Assets may include items such as transformers, generators, transmission lines, distribution lines, capacitor banks, circuit breakers, surge arresters, as well as instrument sensors such as current transformers (CT), voltage transformers (VT), and capacitor voltage transformers (CVT/CCVT).

If any of the assets becomes damaged or otherwise malfunctions, a portion of the power grid may become at least temporarily inoperable, partially or fully. For example, if one or more transformers becomes damaged, there is a potential for malfunction of a portion of the power distribution grid, which may result in at least a temporary partial power blackout.

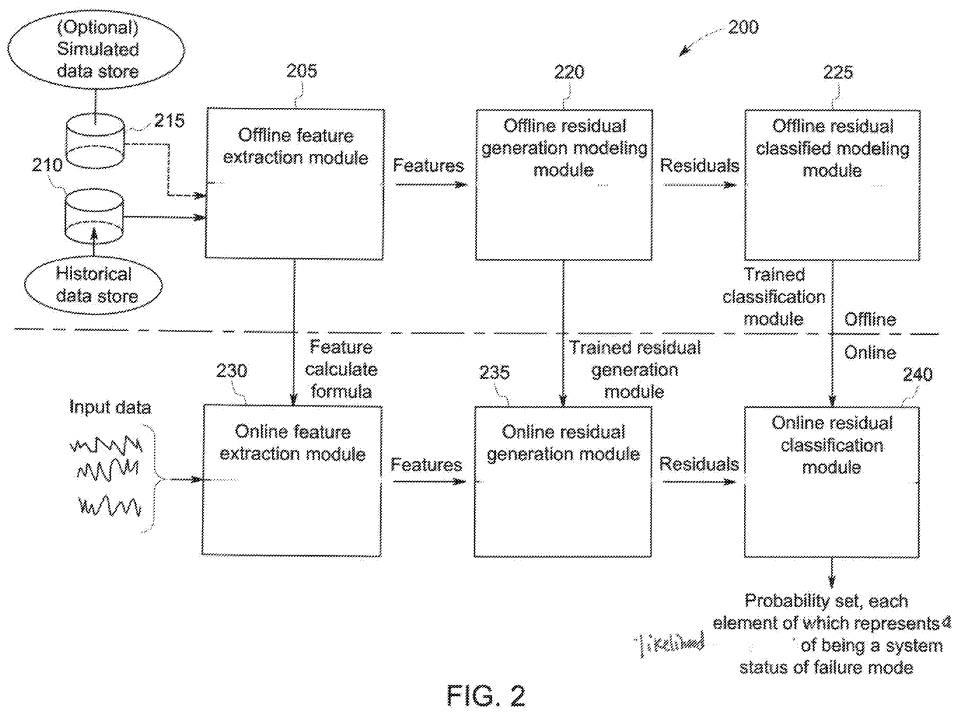

FIG. 2 is a functional block diagram of an embodiment 200 of a Residual-Based Event Diagnosis System (RBEDS) according to an embodiment. An RBEDS may characterize a state of an asset, as is discussed in more detail below. As shown in embodiment 200, the RBEDS may be trained in an offline phase or mode and may subsequently be implemented in an online monitoring and diagnosis phase or application. During an offline phase, training data may be provided to an offline feature extraction module 205. For example, the training data may be received by a receiver of the RBEDS in accordance with an embodiment. The training data may include historical data in an historical data store 210 which may be provided to offline feature extraction module 205. In accordance with an embodiment, the historical data may include PMU and SCADA data, for example. The training data may also optionally include simulated data in a simulated data store 215 which may also be provided to offline feature extraction module 205. Offline feature extraction module 205 may determine and extract various features from raw measurements in the training data. Features determined by feature extraction module 205 may be provided to a residual generation modeling module 220 which may build and/or train one or more residual generation modules. Residual generation modeling module 220 may provide determined residuals to a residual classification modeling module 225 which may train residual-based classifiers.

After the offline training has been completed, for example, an online monitoring and diagnosis phase or application may be performed. For example, an online phase may be performed approximately in real-time in accordance with a particular embodiment. As illustrated, input data may be provided to or otherwise received by an online feature extraction module 230. For example, the input data may be received by a receiver of the RBEDS in accordance with an embodiment. The input data may comprise measurements or data such as PMU and/or SCADA data in accordance with an embodiment. Offline feature extraction module 205 may provide a feature calculation formula or algorithm to online feature extraction module 230, for example. In some embodiments, more than one feature calculation formula may be provided to online feature extraction module 230. Online feature extraction module 230 may apply the feature calculation formula to the input data to calculate or otherwise determine features from the input data and provide those features to an online residual generation module 235. As illustrated in FIG. 2, offline residual generation modeling module 220 may output or otherwise provide a trained residual generation model to online residual generation module 235. In some embodiments, more than one trained residual generation model may be provided from offline residual generation modeling module 220 to online residual generation module 235. Online residual generation module 235 may apply the trained residual model to the extracted features received from online feature extraction module 230 and may determine and output residuals to an online residual classification module 240. As illustrated, offline residual generation modeling module 225 may output or otherwise provide a trained classification model to online residual classification module 240. A “classification model” may be referred to herein as a “classifier,” for example. In some embodiments, more than one trained classification model may be provided by offline residual classification modeling module 225 to online residual classification module 240, for example. Online residual classification module 240 may, for example, apply the trained classification model to the residuals output by online residual generation module 235 to obtain a status of a power grid system and/or one or more assets of the power grid system. Online residual classification module 240 may generate and output a probability set, each element of which may represent a likelihood of a system status or failure mode, for example.

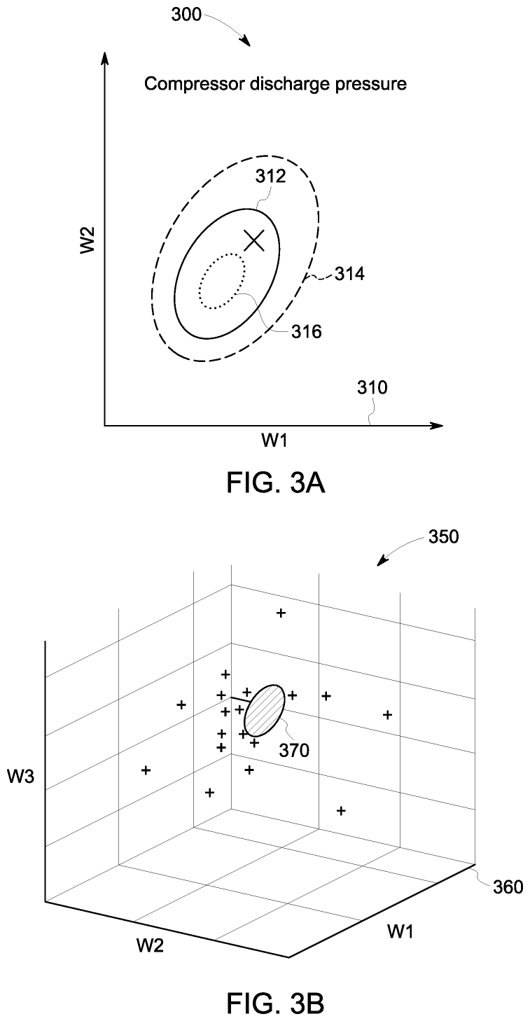

FIGS. 3A and 3B illustrate features, feature vectors, and decision boundaries in accordance with some embodiments. As used herein, the phrase “decision boundaries” and the term “classifiers” may be used interchangeably and may have the same meaning. In particular, FIG. 3A illustrates 300 boundaries and feature vectors for a monitoring node parameter for a node of a power grid system in accordance with some embodiments. A graph 310 includes a first axis representing value weight 1 (“w1”), a feature 1, and a second axis representing value weight 2 (“w2”), a feature 2. Values for w1 and w2 may be associated with, for example, outputs from a Principal Component Analysis (“PCA”) performed on input data. PCA may be one of the features that may be used by the algorithm to characterize the data, but it should be appreciated that other features could be leveraged. The graph 310 illustrated in FIG. 3A represents compressor discharge temperature for a gas turbine but other values may be monitored instead (e.g., compressor pressure ratio, compressor inlet temperature, fuel flow, generator power, gas turbine exhaust temperature, etc.). The graph 310 includes an average boundary 312 (solid line), minimum boundary 314 (dotted line), and maximum boundary 316 (dashed line) and an indication associated with current feature location for the monitoring node parameter (illustrated with an “X” on the graph 310). As illustrated in FIG. 3A, the current monitoring node location is between the minimum and maximum boundaries (that is, the “X” is between the dotted and dashed lines). As a result, the system may determine that the operation of the industrial asset is normal (e.g., and no anomaly or fault is being detected for that monitoring node).

FIG. 3B illustrates 350 three dimensions of threat node outputs in accordance with some embodiments. In particular, a graph 360 plots monitoring node outputs (“+”) in three dimensions, such as dimensions associated with PCA: w1, w2, and w3. Moreover, the graph 360 includes an indication of a normal operating space decision boundary 370. Although a single contiguous boundary 370 is illustrated in FIG. 3B, embodiments may be associated with multiple regions (e.g., associated with anomaly and fault regions).

An appropriate set of multi-dimensional feature vectors, which may be extracted automatically (e.g., via an algorithm) and/or be manually input, may comprise a good predictor of measured data in a low dimensional vector space. According to some embodiments, appropriate decision boundaries may be constructed in a multi-dimensional space using a data set which is obtained via scientific principles associated with Design of Experiments (“DoE”) techniques. Moreover, multiple algorithmic methods (e.g., support vector machines or machine learning techniques) may be used to generate decision boundaries. Since boundaries may be driven by measured data (or data generated from high fidelity models), defined boundary margins may help to create a threat zone in a multi-dimensional feature space. Moreover, the margins may be dynamic in nature and adapted based on a transient or steady state model of the equipment and/or be obtained while operating the system as in self-learning systems from incoming data stream. According to some embodiments, a training method may be used for supervised learning to teach decision boundaries. This type of supervised learning may take into account an operator's knowledge about system operation (e.g., the differences between normal and abnormal operation).

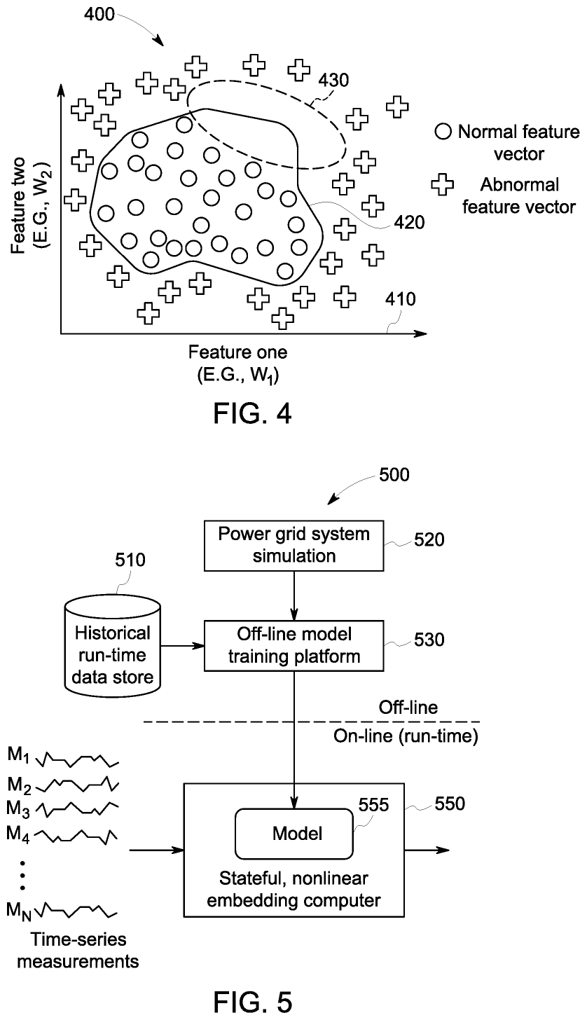

FIG. 4 is a schematic view 400 of a region likely to be left out while running various abnormal/operational scenarios (e.g., regions without data for boundary computation). In particular, a two-dimensional feature space is graphed 410 includes a decision manifold or boundary 420 dividing normal space (within the boundary 420) from abnormal space (outside the boundary 420. As illustrated by the region 430 (illustrated by a dashed line in FIG. 4), there may be areas of the feature space were no data is available (that is, there are no normal or abnormal examples within the region 430). It may therefore be desirable to include domain level control system features in addition to engineered features from monitoring.

One or more embodiments, as discussed herein, may provide a unified system to classify the status of an industrial control system having a plurality of monitoring nodes (including sensor, actuator, and controller nodes) as being normal, experiencing an anomaly, or fault. Some embodiments comprise a collection of layered multi-class classifiers which together determine the status of each monitoring node as being normal, experiencing an anomaly, or faulty (and, in some cases, may also categorize the type of fault that has occurred). The multi-class decision systems may be arranged in various configurations of interconnected classifiers. For a particular application, these configurations may exhibit different performance and computational demands. An appropriate configuration may be selected for an available data set based on required performance and available online computational power. This selection may be automatically performed by an algorithm, for example.

According to some embodiments, time-series data may be received from a collection of monitoring nodes (e.g., sensor, actuator, and/or controller nodes). Features may then be extracted from the time series data for each monitoring node. The term “feature” may refer to, for example, mathematical characterizations of data. Examples of features as applied to data may include the maximum and minimum, mean, standard deviation, variance, settling time, Fast Fourier Transform (“FFT”) spectral components, linear and non-linear principal components, independent components, sparse coding, deep learning, etc. The type and number of features for each monitoring node, may be optimized using domain-knowledge, feature engineering, or ROC statistics. The features may be calculated over a sliding window of the signal time series and the length of the window (and the duration of slide) may be determined from domain knowledge and inspection of the data or using batch processing.

According to some embodiments, information about anomalies or faults, for example, may be provided to models and/or a training and evaluation database created using DoE techniques. The models may, for example, simulate data from monitoring nodes to be used to compute features that are assembled into a feature vector to be stored in a training and evaluation database. The data in the training and evaluation database may then be used to compute decision boundaries to distinguish between normal operation, anomaly operation, and fault operation. According to some embodiments, the models may comprise high fidelity models that can be used to create a data set (e.g., a set that describes anomaly and/or fault space). The data from the monitoring nodes may be, for example, quantities that are captured for a particular length of time from sensor nodes, actuator nodes, and/or controller nodes (and a similar data set may be obtained for “levels of normal operating conditions in the system versus quantities from the monitoring nodes”).

It should be appreciated that many different types of features may be utilized in accordance with any of the embodiments described herein, including principal components (weights constructed with natural basis sets) and statistical features (e.g., mean, variance, skewness, kurtosis, maximum, minimum values of time series signals, location of maximum and minimum values, independent components, etc.). Other examples include deep learning features (e.g., generated by mining experimental and/or historical data sets) and frequency domain features (e.g., associated with coefficients of Fourier or wavelet transforms). Embodiments may also be associated with time series analysis features, such as cross-correlations, auto-correlations, orders of the autoregressive, moving average model, parameters of the model, derivatives and integrals of signals, rise time, settling time, neural networks, etc. Still other examples include logical features (with semantic abstractions such as “yes” and “no”), geographic/position locations, and interaction features (mathematical combinations of signals from multiple monitoring nodes and specific locations). Embodiments may incorporate any number of features, with more features allowing the approach to become more accurate as the system learns more about a particular anomaly, for example. According to some embodiments, dissimilar values from monitoring nodes may be normalized to unit-less space, which may allow for a simple way to compare outputs and strength of outputs.

PCA information may be represented as weights in reduced dimensions. For example, data from each monitoring node may be converted to low dimensional features (e.g., weights). According to some embodiments, monitoring node data may be normalized as follows:

$${S}_{normalized} ( k ) = \frac{{S}_{nominal} ( k ) - {S}_{original} ( k )}{{\overline{S}}_{nominal}} \qquad [ Relation 1 ]$$

where S stands for a monitoring node quantity at “k” instant of time. Moreover, output may then be expressed as a weighted linear combination of basis functions as follows:

$$S = {S}_{0} + {\sum }_{j = 1}^{N} {w}_{i} {Ψ}_{j} \qquad [ Relation 2 ]$$

where S₀ is the average monitoring node output with all threats, wⱼ is the j^{th} weight, and Ψⱼ is the j^{th} basis vector. According to some embodiments, natural basis vectors may be obtained using a covariance of the monitoring nodes' data matrix. Once the basis vectors are known, a weight may be found using the following equation (assuming that the basis sets are orthogonal):

wⱼ=(S−S₀)^{T}Ψⱼ [Relation 3]

Note that weights may be an example of features used in a feature vector.

Thus, once the observed quantities from monitoring nodes are expressed in terms of feature vectors (e.g., with many features), the feature vectors may then be used as points in a multi-dimensional feature space. During real-time anomaly or threat detection, decisions may be made by comparing where each point falls with respect to a decision boundary that separates the space between two regions (or spaces): abnormal (“anomaly” or “fault”) space and normal operating space. If the point falls in the abnormal space, the industrial asset is undergoing an abnormal operation such as during an anomaly. If the point falls in the normal operating space, the industrial asset is not undergoing an abnormal operation such as during an anomaly. Appropriate decision zone with boundaries are constructed using data sets as described herein with high fidelity models. For example, support vector machines may be used with a kernel function to construct a decision boundary. According to some embodiments, deep learning techniques may also be used to construct decision boundaries.

Some embodiments described herein may provide a system and method for abstracting underlying system characteristics of a power grid system. Specifically, a system and method may perform abstraction by stateful, nonlinear embedding of real-time system measurements, such as sensors, actuators and control, of the power grid system. Given the fact that such systems have a complex and dynamic nature and system measurements may be noisy, some embodiments may effectively eliminate redundant and irrelevant information from the noisy measurements, while still capturing complex temporal dependence among the measurements (thus preserving the underlying system characteristics). The abstracted characteristics may be further utilized as features or signatures for building effective predictive models, e.g., anomaly and/or fault detection, localization, and/or neutralization.

A “stateful,” nonlinear embedding computer may receive, from a data source, a plurality of time-series measurements that represent normal operation of a power grid system. As used herein, the term “stateful” may refer to a program or process designed to remember preceding events. According to some embodiments, the plurality of time-series measurement may be received in substantially real time during online operation of the power grid system. At least one of the time-series measurements may be associated with, for example, a sensor monitoring node (e.g., measuring an attribute associated with the power grid system), an actuator monitoring node, and/or a control monitoring node.

A stateful, nonlinear embedding may be performed or executed to project the plurality of time-series measurements to a lower-dimensional latent variable space such that redundant and irrelevant information are reduced and temporal and spatial dependence among the measurements are captured. The stateful, nonlinear embedding may be associated with a deep neural network, an autoencoder, a variational autoencoder, and/or a generative adversarial network, to name just a few examples among many.

For example, a stateful, nonlinear embedding may augment a stateless, nonlinear embedding process by using a window of consecutive samples of the time-series measurements as a matrix input to the stateless, nonlinear embedding process. As another example, a stateful, nonlinear embedding may augment a stateless embedding process by using a first independent sample of the time-series measurements as a first vector input to the stateless embedding to receive a first output. The system may then use a second independent sample of the time-series measurements as a second vector input to the stateless embedding to receive a second output. Statistics of the first and second outputs may then be calculated with post-processing to obtain lower-dimensional latent variable space.

According to some embodiments, the stateful, nonlinear embedding is associated with a recurrent “autoencoder.” As used herein, an “autoencoder” refers to, for example, an artificial neural network used for unsupervised learning of efficient codes to learn a representation (encoding) for a set of data (e.g., to achieve dimensionality reduction). For example, the recurrent autoencoder may be implemented using a stateful “generative adversarial network.” As used herein, “generative adversarial network” refers to, for example, a class of artificial intelligence algorithms used in unsupervised machine learning implemented by a system of two neural networks contesting with each other in a zero-sum game framework. A stateful generative adversarial network may include, for example, a generator (e.g., having a recurrent neural network encoder and a recurrent neural network decoder) and a discriminator with a deep network. According to some embodiments, a generator is further associated with long short-term memory. Many of these techniques, in their original form, were not designed for dynamic system applications (e.g., they are “stateless”).

Appropriate stateful, nonlinear embedding for a particular cyber-physical system may be achieved in a number of different ways. For example, FIG. 5 illustrates a system 500 that may create stateful, nonlinear embedding in accordance with some embodiments. System 500 may include a stateful, nonlinear embedding computer 550 to receive time-series measurements online during run-time (e.g., while power grid system and/or one or more associated assets are operational or otherwise running). The stateful, nonlinear embedding computer 550 may execute a model 555 that was previous created offline (e.g., before the current operation of the power grid system and/or asset(s)). According to some embodiments, the model may be created by an offline model training platform 530 based on, for example, information from a historical run-time data store 510 (e.g., data collected over several months of normal operation of the power grid system and/or asset(s)) and/or information from a power grid system and/or asset(s) simulation (e.g., a high-fidelity physics model that simulates operation of the power grid system and/or asset(s)).

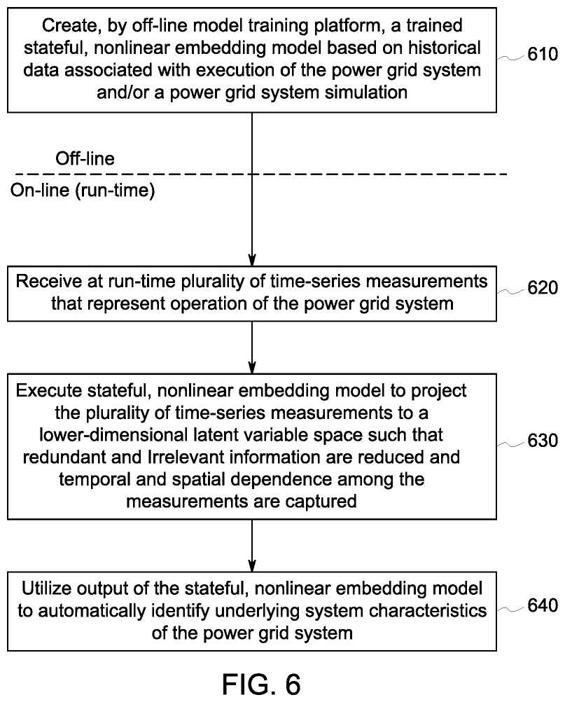

FIG. 6 illustrates a method to create stateful, nonlinear embedding in accordance with some embodiments. Embodiments in accordance with claimed subject matter may include all of, less than, or more than blocks 610 through 640. Also, the order of blocks 610 through 640 is merely an example order. At operation 610, an offline model training platform may create a trained stateful nonlinear embedding model. For example, data may be recorded during normal operation of a gas turbine over a period of several month (e.g., and the recorded data may be stored in a historical data store). This information may then be used offline to train a stateful, nonlinear embedding model. According to some embodiments, a high-fidelity simulation may be used to generate data that can be used to train the model (e.g., instead of or in addition to actual historical data). Later, during online run-time, time-series measurements that represent operation of the cyber-physical system may be received at operation 620. A stateful, nonlinear embedding model may then be executed at operation 630 (e.g., to project the measurements to a lower dimensional latent variable space such that redundant and/or irrelevant information may be reduced while temporal and/or spatial dependence among the measurements are captured). At 640, the system may utilize the output of the stateful, nonlinear embedding model to automatically identify underlying characteristics of the power grid system and/or asset(s).

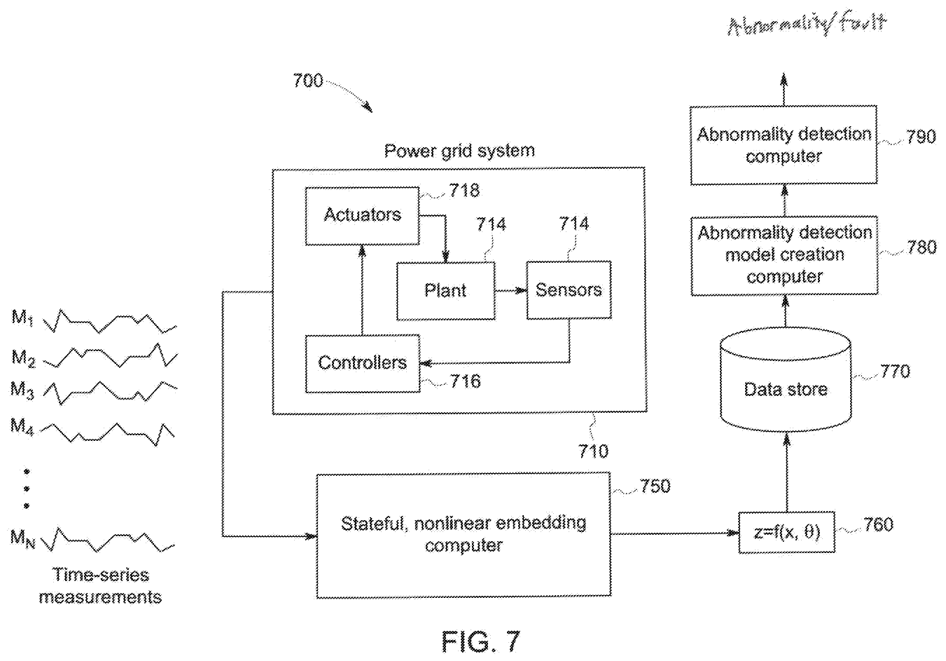

Embodiments described herein may abstract power grid system and/or asset characteristics and may handle both spatial and temporal dependences of the underlying system. FIG. 7 illustrates an abnormality detection system 700 for an industrial asset in accordance with some embodiments. As before, a stateful, nonlinear embedding computer 750 may receive a time-series of measurements (Mi through MN). The time-series of measurements may be received, for example, from a power grid system 710. The power grid system 710 may include a plant 712 (e.g., associated with an industrial asset) that provides information to controllers 716 via sensors 714. Power grid system 710 may also include one or more substations, for example. The controllers 716 may operator actuators 718 that send data to the plant 712. By analyzing the time-series measurements, the stateful, nonlinear embedding computer 750 may create a latent representation 760 (e.g., a function such as z=f(x, θ) or the like). The latent representation 760 may be stored in a data store 770 accessed by an abnormality detection model creation computer 780. The abnormality detection model creation computer 780 may create feature vectors in feature space and generate a decision boundary separating normal operation of the system 710 from abnormal operation (e.g., during a fault or cyber-threat). An abnormality detection computer 790 may then use the decision boundary (along with current measurements from the system 710 converted into feature space during online operation) for anomaly detection, fault detection, abnormality localization, and/or abnormality neutralization, to name just a few examples among many.

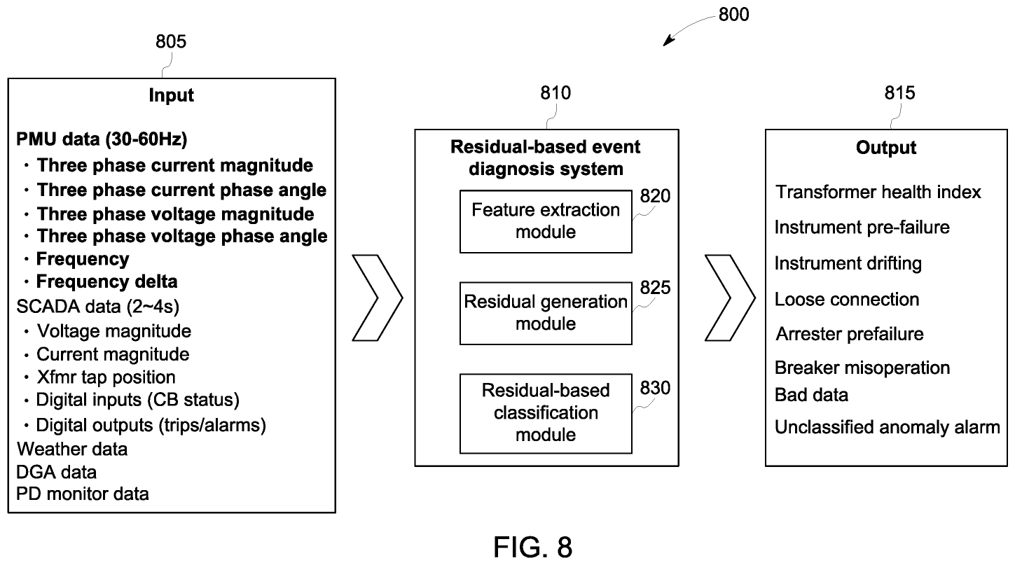

FIG. 8 illustrates an embodiment 800 a system diagram of a RBEDS 810 and corresponding inputs 805 and outputs 815 according to an embodiment. As illustrated, various inputs may include PMU data (30-60 Hz), SCADA data (e.g., at 2-4 seconds), weather data, DGA data, and PD monitor data, for example. PMU data may include three phase current magnitude, three phase current phase angle, three phase voltage magnitude, three phase voltage phase angle, frequency, and frequency delta, for example. SCADA data may include voltage magnitude, current magnitude, transformer (Xfmr) tap position, digital inputs (e.g., circuit breaker (CB) status), and digital outputs (e.g., trips/alarms), for example.

Various outputs are shown in FIG. 8, such as a transformer health index, instrument pre-failure, instrument drifting, loose connection, arrester pre-failure, breaker mis-operation, bad data, and unclassified anomaly alarm, to name just a few examples among many.

RBEDS 810 may receive the inputs 805 and generate the outputs 815. RBEDS 810 may include, e.g., a feature extraction module 820, a residual generation module 825, and a residual-based classification module 830.

Considering the complex and dynamic nature of substations, feature extraction, a technique of transforming the noisy raw data/measurements to salient, information-rich signatures/features, may comprise a key aspect to the success of event diagnosis. A system in accordance with one or more embodiments may explore various features which may capture spatial and temporal effects in the large numbers of measurements from different data sources (e.g., PMU, state estimator, etc.) using techniques from different technical domains including knowledge-based, statistical-based, signal processing-based (e.g., fast Fourier transform (FFT)), transformation-based (e.g., Principal component analysis (PCA)), and learning-based, for example. While a system in accordance with one or more embodiments is flexible and incorporates a variety of features from different domains, knowledge-based features which correlate well with events and are better in distinguishing different asset problems (e.g., deteriorating equipment and/or erroneous machine settings) may be critical data sources.

Feature extraction module 820 may calculate various features over a sliding window of time-series measurements of input data, such as PMU data and/or SCADA data, for example. To tackle an issue where different data may have different sampling rates, features calculations may be performed separately for different data sources over the sliding window and may subsequently be concatenated together (e.g., via feature-level fusion) to form a feature vector for each sliding window, for example.

Residual generation module 825 may generate residuals, multiple physical models of subsystems or components of the substation are built first for capturing the underlying system's physical behaviors under normal operation conditions. A “residual” of “residual of an observed value,” as used herein, refers to a difference between an observed value and an estimated value of a measurement or quantity of interest such as a sample mean. For example, a residual may comprise a difference between a signature determined based off measured input data and estimated values.

Physical models utilized by RBEDS 810 may be built using first principal or data-driven methods, for example. First principal models may often be built in an original measurements space, while data-driven models may often be built in a feature space. The data-driven models may be built using one of many methods available, such as density estimation-based (e.g., Gaussian mixture models), instance-based (e.g., similarity-based modeling), and/or auto-associative neural networks, e.g., auto-encoders, to name just a few examples among many.

Given the fact that the number of features generated from original raw measurements may be potentially large, feature dimensionality reduction, such as, feature selection, feature transformation (e.g., PCA), and low dimension embedding, e.g., may be employed such that the data-driven model can be built in a lower-dimensional feature space to improve the model performance (accuracy and robustness). To further reduce model complexity and improve model performance, the entire feature space can be divided into multiple subspaces based on, for example, nature cluster/groups of the normal data distributions in the feature space or system hierarchy of the substation. A separate model can be built for each of the subspaces.

With the physical models (first principal and/or data-driven) well built, residuals, the differences between the models' predictions and the actual measurements, are calculated for each data sample or time stamp. These residuals are expected to be small (close to zero mean) at normal condition, which can be used for anomaly detection. Different failure modes of different subsystems or components may signify different residual patterns, allowing for the pinpointing of particular components or subsystems which have contributed to an event observed.

Residual-based classification module 830 may utilize the residuals extracted by residual generation module 825. For example, residual-based classification module 830 may map the residuals to a set of failure modes, and/or a status of subsystems of the substation may subsequently be built. Depending on how many events data with known failure modes are available, the residual-based classification module 830 may implement a model which is rule-based, instance-based, and/or a learning-based, for example.

Residual-based classification module 830 may implement a model which comprises a model or a combination of multiple (e.g., hybrid) models. In an implementation utilizing multiple models, the multiple models may be of different types, such as, e.g., rule-based and neural networks, and each of the models may be independently designed for monitoring a subsystem or a component of the substation.

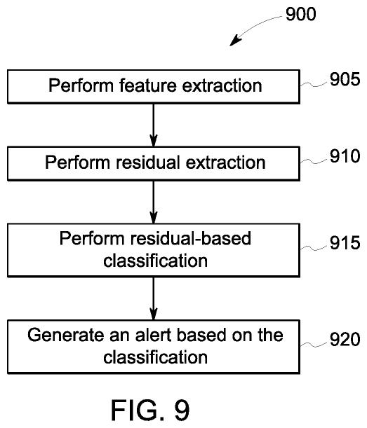

FIG. 9 illustrates an embodiment 900 of a process for performing residual-based event diagnosis. For example, embodiment 900 may comprise a process which may be implemented by RBEDS 810 of embodiment 800 as shown in FIG. 8. Embodiments in accordance with claimed subject matter may include all of, less than, or more than blocks 905 through 920. Also, the order of blocks 905 through 920 is merely an example order.

At operation 905, feature extraction may be performed based on various inputs received by an RBEDS, such as RBEDS 810 of embodiment 800, for example. At operation 910, residual extraction may be performed to determine a residual comprise a different between expected data values and actual observed data values. At operation 915, a residual-based classification may be performed to, e.g., classify an anomaly or other event based on a measured residual. At operation 920, an alert may be generated to alert an operator based on the classification. For example, if the classification indicates that a particular transformer is about to fail, an alert may be generated to inform a human operator that the transformer should be replaced.

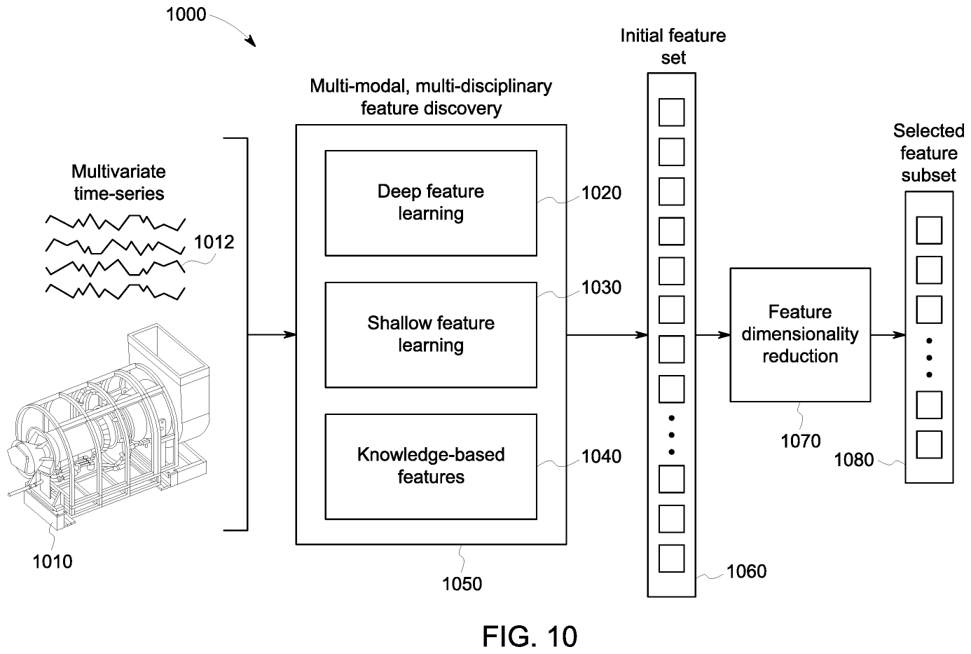

FIG. 10 is a feature vector information flow diagram 1000 wherein a heterogeneous set of data sources are associated with an industrial asset 1010. For example, a method in accordance with feature vector flow diagram 1000 may be utilized to perform feature extraction, such as in accordance with embodiment 800 of FIG. 8. The data sources may include, for example, multivariate time-series information 1012 (e.g., from sensor nodes) that is provided to multi-modal multi-disciplinary (MMMD) feature discovery 1050 which generates an initial feature set 1060. The MMMD feature discovery 1050 may include, according to some embodiments, deep feature learning 1020, shallow feature learning 1030, and/or knowledge-based features 1040. Because the initial feature set 1060 may be relatively large, a feature dimensionality reduction process 1070 may be utilized to create a selected feature subset 1080.

The information flow diagram 1000 may achieve improved detection performance by maximally leveraging information from both conventional sensor data (e.g., sensor measurements from gas turbines) and unconventional data through multi-modal, multi-disciplinary feature discovery 1050. Given the heterogeneous data types, the system may extract features from each individual data source using different feature extraction methods and then combine the results to create the initial feature set 1060 (this “combining” process is often referred as “feature fusion” in machine learning and data-mining domains). Because the initial feature set 1060 is likely substantially large, the system then applies feature dimensionality reduction 1070 techniques to reduce the number of features to a reasonable level before the selected feature subset 1080 is used by an anomaly detection engine.

Note that the MMMD feature discovery 1050 may include some or all of knowledge-based feature 1040 engineering, shallow feature learning 1030, and deep feature learning 1020. Knowledge-based feature 1040 engineering may use domain or engineering knowledge of gas turbine 1010 physics to create features from different sensor measurements. These features may simply be statistical descriptors (e.g., maximum, minimum, mean, variance, different orders of moments, etc.) calculated over a window of a time-series signal and its corresponding Fast Fourier Transformation (“FFT”) spectrum as well. The knowledge-based features 1040 may also utilize a power system analysis, such as basis vector decomposition, state estimation, network observability matrices, topology matrices, system plant matrices, frequency domain features and system poles and zeros. These analyses may represent a characterization of the current gas turbine 1010 operation through steady-state, transient, and small signal behaviors.

Although knowledge-based feature 1040 engineering is a traditional approach for feature extraction, it is often a laborious, manual process. The approach is also very application specific, and therefore not generalizable or scalable. Learning features directly from data (e.g., via machine learning) may address these issues. For example, shallow feature learning 1030 techniques include many unsupervised learning (e.g., k-means clustering), manifold learning and nonlinear embedding (e.g., isomap methods and Locally-Linear Embedding (“LLE”)), low-dimension projection (e.g., Principal Component Analysis (“PCA”) and Independent Component Analysis (“ICA”)), and/or neural networks (e.g., Self-Organizing Map (“SOM”) techniques). Other examples of shallow feature learning 1030 techniques include genetic programming and sparse coding. The deep feature learning 1020 may represent a sub-field of machine learning that involves learning good representations of data through multiple levels of abstraction. By hierarchically learning features layer by layer, with higher-level features representing more abstract aspects of the data, deep feature learning 1020 can discover sophisticated underlying structure and features.

The multi-modal, multi-disciplinary feature discovery 1050 (or “extraction”) will most likely lead to a large number of features in the initial feature set 1060. Moreover, many redundant features may exist. Directly using such a large number of features may be burdensome for down-stream anomaly detection models. As a result, feature dimensionality reduction 1070 may reduce the number of features by removing redundant information while maximally preserving useful information of the features. Embodiments described herein may be associated with feature selection and/or feature transformation techniques.

By combining knowledge-based feature 1050 engineering and advanced deep feature learning 1020 techniques (and applying those to different data sources), the MMMD feature discovery 1050 framework may be effective in discovering a feature set that provides accurate and reliable threat detection. Note that the framework is generic (and can be used effectively for other analytics applications) and flexible in handling situations where the numbers and the types of available data sources vary from system to system.

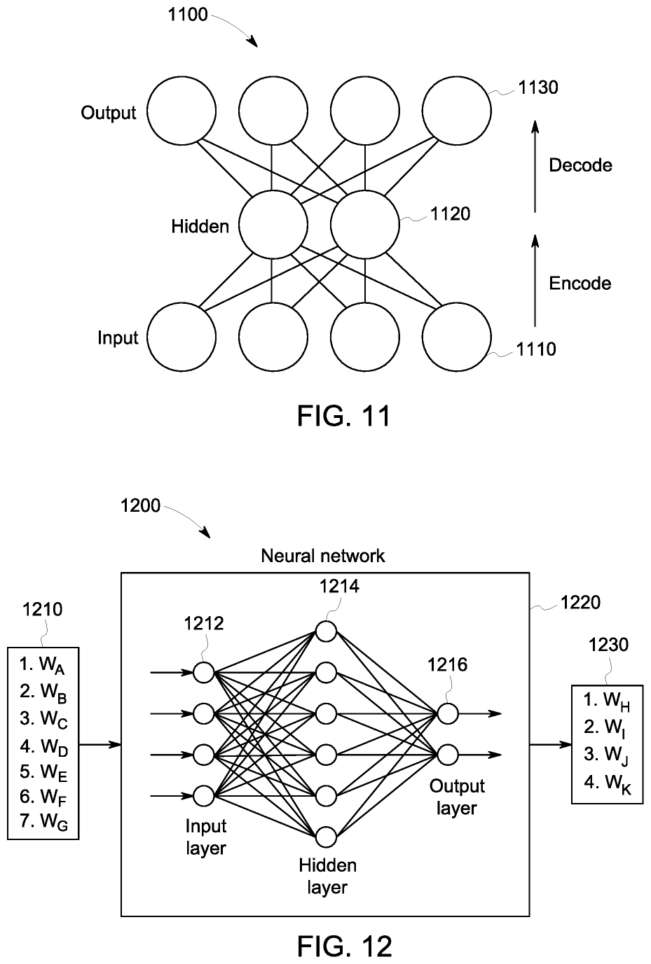

FIG. 11 illustrates layers of an autoencoder algorithm 1100 in accordance with some embodiments. For example, autoencoder algorithm 1100 may be utilized to implement a residual generation model in accordance with embodiment 800 of FIG. 8. In particular, an encode process may turn raw inputs 1110 (e.g., time-series measurements) into hidden layer 1120 values. A decode process turns the hidden layer 1120 values into output 1130 (e.g., the latent representation). Note that the number of hidden nodes may be specified and may correspond to a number of features to be learned. According to some embodiments, an autoencoder may be constructed as an optimization problem. For example, the error function, mean-squared error to minimize and find W, b, and d′ may be performed as follows:

min E(W,b,d′)=min_{W,b,d′Σ}Σⱼ₌₁^{p}∥xⱼ−g_{θ}(ƒ_{θ}(xⱼ))∥² [Relation 4]

where xⱼ corresponds to samples of data and P is equal to the number of samples.

Note that an autoencoder implementation may use the cross entropy error function instead of mean squared error. Moreover, an expected value may be required when using cross entropy:

min E(W,b,d′)=min_{W,b,d′}E[L((x,z)] [Relation 5]

where L(x, z) is the cross-entropy loss L(x, z) shown above.

Broadly speaking, there may be two categories of strategies to achieve stateful embedding. The first one is to augment existing stateless embedding to make it stateful. For example, instead of taking an independent sample (an input vector) as the input to the stateless embedding, a system may take a window of consecutive samples (a matrix) as the input to the embedding, enabling the resultant embedding to be temporal dependent.

FIG. 12 show neural network model structures corresponding to functions ƒ₁ (and similar networks may be defined for ƒ₂, and ƒ₃). In particular, FIG. 12 illustrates 1200 inputs 1210 of ƒ₁ being provided to neural network 1220 (including an input layer 1212, a hidden layer 1214, and an output layer 1216) which in turn creates an output (namely, W_{H}, W_{I}, W_{J}, and W_{K}).

According to some embodiments, a comparison can be made between predicted and measured output as well as the prediction errors in terms of Mean Absolute Percentage Error (“MAPE”) corresponding to these three functions. It is worth noting that the three neural network models could be trained and tested based on the normal data set only. However, training can be done with both normal and abnormal data set, if the models provide values for other quantities not used in the monitoring nodes.

With the three functions being properly derived through neural network modeling, the system may construct features in a number of different ways: one way may directly use the outputs of the neural network models as features while another may use the residuals as the features (that is, the difference between the neural network outputs and the measured output corresponding to each input). Such obtained domain-level features may then be combined with the data-driven features and used as inputs to a detection engine in accordance with any of the embodiments described herein.

The extensions to features with domain-level functions may help overcome limitations of the solely data-driven approach, especially when normal and abnormal spaces are not fully explored during training stage. Some embodiments may also provide a good framework to incorporate actual control functions into features when access to such functions is available (e.g., gas turbines). The method may be applicable to any new asset from any Original Equipment Manufacturer (“OEM”) provider since time series signals can be used to construct the domain-specific controller function models.

Some advantages associated with embodiments described herein may include: a flexible ability to generate features for any number/type of monitoring directly from control functions embedded in the system; making detection more sensitive to load transients (e.g., load sweeps), and providing accurate feature evolution by capturing dynamics of the system. Moreover, embodiment may be associated with an analytics application for an industrial asset modeling and/or monitoring portfolio of applications.

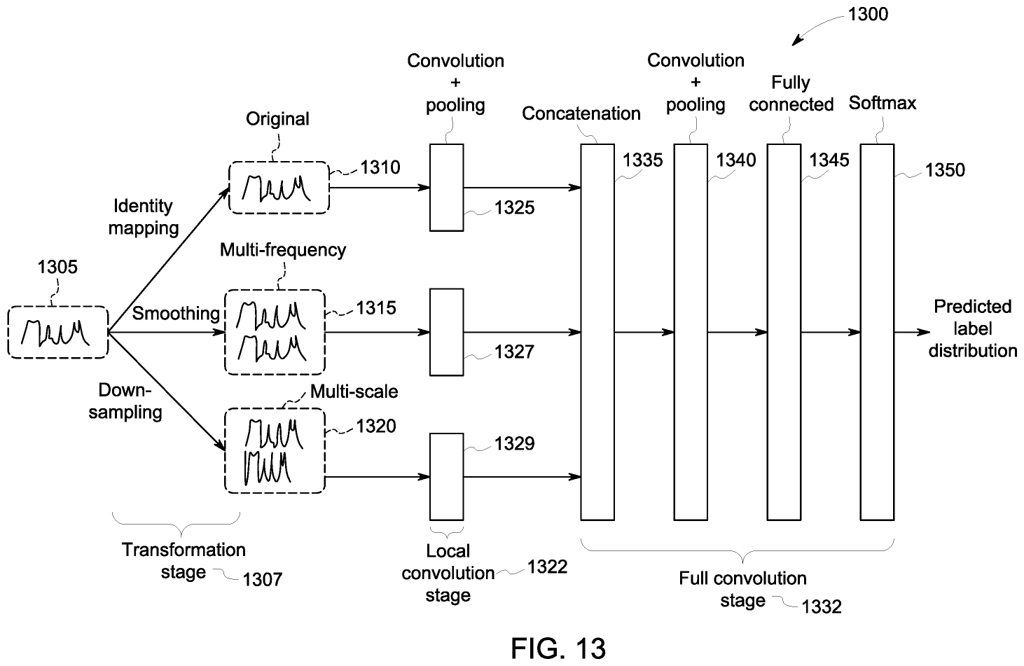

FIG. 13 illustrates an embodiment 1300 of a multi-scale convolutional neural network (MCNN) framework. MCNN embodiment 1300 include three sequential stages: a transformation 1307, a local convolution stage 1322, and a full convolution stage 1332.

As illustrated, an input time series may be received at input box 1305. A transformation stage 1307 may apply various transformations on an input time series. Examples of transformations include identity mapping, down-sampling transformations in the time domain, and spectral transformations in the frequency domain, for example. Identity mapping may be applied to the input time series and provided to a first processing block 1310 comprising the original time series. A smoothing operation may be applied to the input time series and provided to a second processing block 1315 comprising a multi-frequency time series. A down-sampling operation may be applied to the input time series and provided to a third processing block 1320 comprising a multi-scale time series. Each portion of a stage may be referred to as a branch, as it is a branch input to a convolutional neural network, for example.

In a local convolution stage 1322, several convolutional layers, such as boxes 1325, 1327, and 1329, may be utilized to extract features for each branch. In this stage, convolutions for different branches may be independent from each other. All outputs may pass through a max pooling procedure with multiple sizes.

In a full convolution stage, extracted features may be concatenated at box 1335. Additional convolutional layers may be applied (e.g., with each followed by max pooling) at box 1320. At box 1345, fully connected operations may be performed. A softmax operation may be performed at box 1350 to generate the final output. A softmax function may take as input a vector of K real numbers and may normalize it into a probability distribution consisting of K probabilities proportional to the exponentials of the input numbers. Embodiment 1300 may comprise an entirely end-to-end system and all parameters may be trained jointly through back propagation.

A distinctive feature of MCNN, e.g., is that its first layer contains multiple branches that perform various transformations of the time series, including those in the frequency and time domains, for extracting features of different types and time scales. Subsequent convolutional layers may apply dot products between transformed waves and 1-D learnable filters, which may therefore comprise a general way to automatically recognize various types of features from an input. As a single convolutional layer may detect local patterns similar to shapelets, stacking multiple convolutional layers may construct more complex patterns, for example. Utilizing this network structure, autocorrelation (ACF) and power spectrum (PS) transforms may be added or otherwise applied in a transformation stage. A Teager-Kaiser energy tracking operator (TKEO) transform may additionally be added for frequency variables, symbolic transformation, and/or image embedding transformations, which may further improve classification performance, for example.

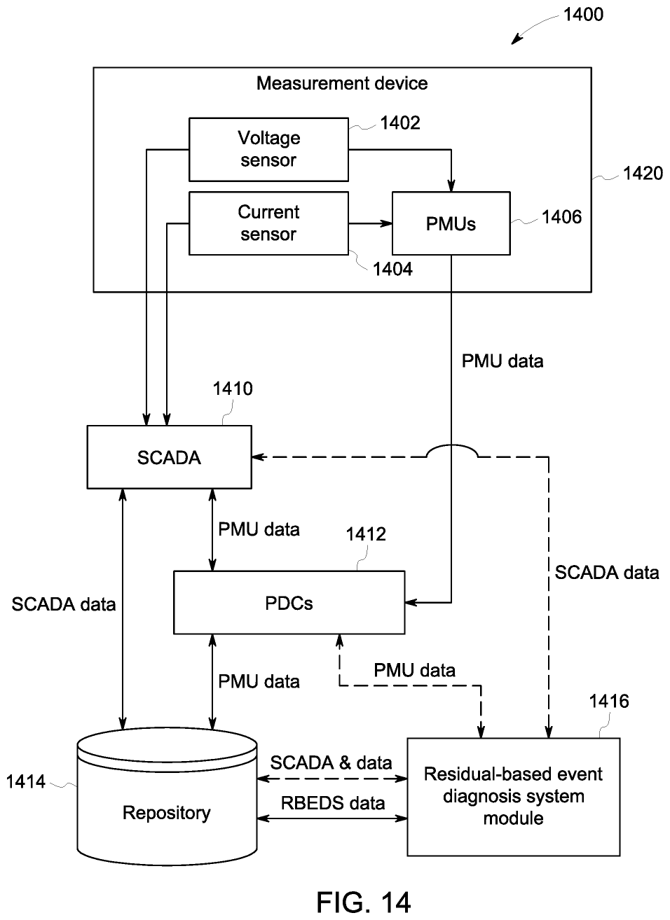

FIG. 14 illustrates a power grid system 1400 including a residual-based event diagnosis system (RBEDS) module 1416 in accordance with an example embodiment. For example, a server may implement RBEDS module 1416. In this example, the RBEDS module 1416 may monitor the health of one or more assets of a power grid system and/or of the grid itself. In some embodiments, the RBEDS module 1416 may also store and display asset health history for one or more assets and/or of the grid itself and a variety of other statistical information related to disturbances and events, including on a graphical user interface, or in a generated report, for example.

A measurement device 1420 shown in FIG. 14 may obtain, monitor or facilitate the determination of electrical characteristics associated with the power grid system (e.g., the electrical power system), which may comprise, for example, power flows, voltage, current, harmonic distortion, frequency, real and reactive power, power factor, fault current, and phase angles. Measurement device 1420 may also be associated with a protection relay, a Global Positioning System (GPS), a Phasor Data Concentrator (PDC), communication capabilities, or other functionalities.

Measurement device 1420 may provide real-time measurements of electrical characteristics or electrical parameters associated with the power grid system (e.g., the electrical power system). The measurement device 1420 may, for example, repeatedly obtain measurements from the power grid system which may be used by the RBEDS module 1416. The data generated or obtained by the measurement device 1420 may comprise coded data (e.g., encoded data) associated with the power grid system that may input (or be fed into) a traditional SCADA system. Measurement device 1420 may also comprise one or more PMUs 1406 which may repeatedly obtain subs-second measurements (e.g., 30 times per second). Here, the PMU data may be fed into, or input into, various applications (e.g., Wide Area Monitoring System (WAMS) and WAMS-related applications) that may utilize the more dynamic PMU data (explained further below).

In the example embodiment illustrated in FIG. 14, measurement device 1420 may include a voltage sensor 1402 and a current sensor 1404 that feed data typically via other components, to, for example, a SCADA component 1410. Voltage and current magnitudes may be measured and reported to a system operator every few seconds by the SCADA component 1410. SCADA component 1410 may provide functions such as data acquisition, control of power plants, and alarm display. SCADA component 1410 may also allow operators at a central control center to perform or facilitate management of energy flow in the power grid system. For example, operators may use a SCADA component (e.g., using a computer such as a laptop or desktop) to facilitate performance of certain tasks such opening or closing circuit breakers, or other switching operations which may divert the flow of electricity.

In some examples, the SCADA component 1410 may receive measurement data from Remote Terminal Units (RTUs) connected to sensors in the power grid system, Programmable Logic Controllers (PLCs) connected to sensors in the power grid system, or a communication system (e.g., a telemetry system) associated with the power grid system. PLCs and RTUs may be installed at power plants, substations, and the intersections of transmission and distribution lines, and may be connected to various sensors, including the voltage sensor 1402 and the current sensor 1404. The PLCs and RTUs may receive data from various voltage and current sensors to which they are connected. The PLCs and RTUs may convert the measured information to digital form for transmission of the data to the SCADA component 1410. In example embodiments, the SCADA component 1410 may also comprise a central host server or servers called master terminal units (MTUs), sometimes also referred to as a SCADA center. The MTU may also send signals to PLCs and RTUs to control equipment through actuators and switchboxes. In addition, the MTU may perform controlling, alarming, and networking with other nodes, etc. Thus, the SCADA component 1410 may monitor the PLCs and RTUs and may send information or alarms back to operators over telecommunications channels.

The SCADA component 1410 may also be associated with a system for monitoring or controlling devices in the power grid system, such as an RBEDS system. An RBEDS system may comprise one or more systems of computer-aided tools used by operators of the electric power grid systems to monitor and characterize the health of one or more assets of a power grid system and/or of the grid itself. SCADA component 1410 may be operable to send data (e.g., SCADA data) to a repository 1414, which may in turn provide the data to the RBEDS module 1416. Other systems with which the RBEDS module 1416 may be associated may comprise a situational awareness system for the power grid system, a visualization system for the power grid system, a monitoring system for the power grid system or a stability assessment system for the power grid system, for example.

SCADA component 1410 may generate or provide SCADA data (e.g., SCADA data shown in FIG. 14) comprising, for example, real-time information (e.g., real-time information associated with the devices in the power grid system) or sensor information (e.g., sensor information associated with the devices in the power grid system) that may be used by the RBEDS module 1416. The SCADA data may be stored, for example, in a repository 1414 (described further below). In example embodiments, data determined or generated by the SCADA component 1410 may be employed to facilitate generation of topology data (topology data is further described below) that may be employed by the RBEDS module 1416 to monitor asset health.

The employment of current sensor 1404 and voltage sensor 1402 may allow for a fast response. Traditionally, the SCADA component 1410 monitors power flow through lines, transformers, and other components relies on the taking of measurements every two to six seconds but cannot be used to observe dynamic characteristics of the power system because of its slow sampling rate (e.g., cannot detect the details of transient phenomena that occur on timescales of milliseconds (one 60 Hz cycle is 16 milliseconds). Additionally, although SCADA technology enables some coordination of transmission among utilities, the process may be slow, especially during emergencies, with much of the response based on telephone calls between human operators at the utility control centers. Furthermore, most PLCs and RTUs were developed before industry-wide standards for interoperability were established, and as such, neighboring utilities often use incompatible control protocols.

The measurement device 1420 may also include one or more PMUs 1406. A PMU 1406 may comprise a standalone device or may be integrated into another piece of equipment such as a protective relay. PMUs 1406 may be employed at substations and may provide input into one or more software tools (e.g., WAMS, SCADA, EMS, and other applications). A PMU 1406 may use voltage and current sensors (e.g., voltage sensors 1402, current sensors 1404) that may measure voltages and currents at principal intersecting locations (e.g., substations) on a power grid using a common time source for synchronization and may output accurately time-stamped voltage and current phasors. The resulting measurement is often referred to as a synchrophasor (although the term “synchrophasor” refers to the synchronized phasor measurements taken by the PMUs 1406, some have also used the term to describe the device itself). Because these phasors are truly synchronized, synchronized comparison of two quantities is possible in real time, and this time synchronization allows synchronized real-time measurements of multiple remote measurement points on the grid.

In addition to synchronously measuring voltages and currents, phase voltages and currents, frequency, frequency rate-of-change, circuit breaker status, switch status, etc., the high sampling rates (e.g., 30 times a second) provides “sub-second” resolution in contrast with SCADA-based measurements. These comparisons may be used to assess system conditions such as: frequency changes, power in megawatts (MW), reactive power in mega volt ampere reactive (MVARs), voltage in kilovolts (KV), etc. As such, PMU measurements may provide improved visibility into dynamic grid conditions and/or of asset health and may allow for real-time wide area monitoring of power system and/or asset health dynamics. Further, synchrophasors account for the actual frequency of the power delivery system at the time of measurement. These measurements are important in alternating current (AC) power systems, as power flows from a higher to a lower voltage phase angle, and the difference between the two relates to power flow. Large phase angle differences between two distant PMUs may indicate the relative stress across the grid, even if the PMUs are not directly connected to each other by a single transmission line. This phase angle difference may be used to identify power grid instability, and a PMU may be used to generate an angle disturbance alarm (e.g., angle difference alarm) when it detects a phase angle difference.

Examples of disturbances that may cause the generation of an angle disturbance alarm may comprise, for example, a line out or line in disturbance (e.g., a line out disturbance in which a line that was in service has now gone out of service, or in the case of a line in disturbance, in which case a line that was out of service has been brought back into service). PMUs 1406 may also be used to measure and detect frequency differences, resulting in frequency alarms being generated. As an example, unit out and unit in disturbances may result in the generation of a frequency alarm (e.g., a generating unit was in service, but may have gone out of service, or a unit that was out of service has come back in to service—both may cause frequency disturbances in the system that may result in the generation of a frequency alarm). Still yet, PMUs 1406 may also be used to detect oscillation disturbances (e.g., oscillation in the voltage, frequency, real power—any kind of oscillation), which may result in the generation of an alarm (e.g., oscillation alarm). Several other types of alarms may be generated based on PMU data from PMU based measurements. Although the disturbances mentioned (e.g., line in/out, unit in/out, load in/out) may result in angle or frequency disturbance alarms, an angle or frequency disturbance alarm may not necessarily mean that a particular type of disturbance occurred, only that it is indicative of that type of disturbance. For example, if a frequency disturbance alarm is detected, it may not necessarily be a unit in or unit out disturbance but may be a load in or load out disturbance. The measurement requirements and compliance tests for a PMU 1406 have been standardized by the Institute of Electrical and Electronics Engineers (IEEE), namely IEEE Standard C37.118.

In the example of FIG. 14, one or more Phasor Data Concentrators (PDCs) 1412 are shown, which may comprise local PDCs at a substation. Here, PDCs 1412 may be used to receive and time-synchronized PMU data from multiple PMUs 1406 to produce a real-time, time-aligned output data stream. A PDC may exchange phasor data with PDCs at other locations. Multiple PDCs may also feed phasor data to a central PDC, which may be located at a control center. Through the use of multiple PDCs, multiple layers of concentration may be implemented within an individual synchrophasor data system. The PMU data collected by the PDC 1412 may feed into other systems, for example, a central PDC, corporate PDC, regional PDC, the SCADA component 1410 (optionally indicated by a dashed connector), energy management system (EMS), synchrophasor applications software systems, a WAMS, the RBEDS module 1416, or some other control center software system. With the very high sampling rates (typically 10 to 60 times a seconds) and the large number of PMU installations at the substations that are streaming data in real time, most phasor acquisition systems comprising PDCs are handling large amounts of data. As a reference, the central PDC at Tennessee Valley Authority (TVA), is currently responsible for concentrating the data from over 90 PMUs and handles over 31 gigabytes (GBs) of data per day.

In this example, the measurement device 1420, the SCADA component 1410, and PDCs/Central PDCs 1412, may provide data (e.g., real-time data associated with devices, meters, sensors or other equipment in the power grid system) (including SCADA data and topology data), that may be used by the RBEDS module 1416 for asset health monitoring. Both SCADA data and PMU data may be stored in one or more repositories 1414. In some example embodiments, the SCADA data and PMU data may be stored into the repository 1414 by the SCADA component 1410, or by the PDC 1412. In other embodiments, the RBEDS module 1416 may have one or more components or modules that are operable to receive SCADA data and PMU data and store the data into the repository 1414 (indicated by dashed lines). The repository 1414 may comprise a local repository, or a networked repository. The data on the repository 1414 may be accessed by SCADA component 1410, the PDCs 1412, other systems (not shown), and optionally by example embodiments of the RBEDS module 1416. In example embodiments, the RBEDS module 1416 may be operable to send instructions to one or more other systems (e.g., SCADA component 1410, PDCs 1412) to retrieve data stored on the repository 1414 and provide it to the RBEDS module 1416. In other embodiments, the RBEDS module 1416 may facilitate retrieval of the data stored in repository 1414, directly.

In example embodiments, the data stored in the repository 1414 may be associated SCADA data and PMU data. The data may be indicative of measurements by measurement device 1420 that are repeatedly obtained from a power grid system. In example embodiments, the data in repository 1414 may comprise PMU/SCADA-based equipment data, such as, for example, data associated with a particular unit, line, transformer, or load within a power grid system (e.g., power grid system 1400). The data may comprise voltage measurements, current measurements, frequency measurements, phasor data (e.g., voltage and current phasors), etc. The data may be location-tagged. For example, it may comprise a station identification of a particular station in which a power delivery device being measured is located (e.g., “CANADA8”). The data may comprise a particular node number designated for a location. The data may comprise the identity of the measure equipment (e.g., the identification number of a circuit breaker associated with an equipment). The data may also be time-tagged, indicating the time at which the data was measured by a measurement device. The PMU/SCADA-based equipment data may also contain, for example, information regarding a particular measurement device (e.g., a PMU ID identifying the PMU from which measurements were taken).

In example embodiments, the data stored in repository 1414 may comprise not only collected and measured data from various measurement devices, the data may also comprise data derived from that collected and measured data. The data derived may comprise topology data (e.g., PMU/SCADA-based topology data), event data, and event analysis data, and RBEDS data (data generated by RBEDS module 1416).

In example embodiments, the repository 1414 may contain topology data (e.g., PMU/SCADA-based topology data) indicative of a topology for the power grid system 1400. The topology of a power grid system may relate to the interconnections among power system components, such as generators, transformers, busbars, transmission lines, and loads. This topology may be obtained by determining the status of the switching components responsible for maintaining the connectivity status within the network. The switching components may be circuit breakers that are used to connect (or disconnect) any power system component (e.g., unit, line, transformer, etc.) to or from the rest of the power system network. Typical ways of determining topology may be by monitoring of the circuit breaker status, which may be done using measurement devices and components associated with those devices (e.g., RTUs, SCADA, PMUs). It may be determined as to which equipment has gone out of service, and actually, which circuit breaker has been opened or closed because of that equipment going out of service.

The topology data may be indicative of an arrangement (e.g., structural topology, such as radial, tree, etc.) or a power status of devices in the power grid system. Connectivity information or switching operation information originating from one or more measurement devices may be used to generate the topology data. The topology data may be based on a location of devices in the power grid system, a connection status of devices in the power grid system or a connectivity state of devices in the power grid system (e.g., devices that receive or process power distributed in throughout the power grid system, such as transformers and breakers). For example, the topology data may indicate where devices are located, and which devices in the power grid system are connected to other devices in the power grid system (e.g., where devices in the power grid system are connected, etc.) or which devices in the power grid system are associated with a powered grid connection. The topology data may further comprise the connection status of devices (e.g., a transformer, etc.) that facilitate power delivery in the power grid system, and the statuses for switching operations associated with devices in the power grid system (e.g., an operation to interrupt, energize or de-energize or connect or disconnect) a portion of the power grid system by connecting or disconnecting one or more devices in the power grid system (e.g., open or close one or more switches associated with a device in the power grid system, connect or disconnect one or more transmission lines associated with a device in the power grid system etc.). Furthermore, the topology data may provide connectivity states of the devices in the power grid system (e.g., based on connection points, based on busses, etc.).

In example embodiments, the repository 1414 may contain a variety of event and event analysis data, which may be derived based on PMU data, and in some embodiments, other data as well (e.g., SCADA data, other measurement data, etc.). The data may comprise information regarding the health of one or more assets of the power grid system and/or of the grid itself. The various data stored in the repository 1414, including equipment data, topology data, event data, event analysis data, RBEDS data, and other data, may be inputs into the various functionalities and operations that may be performed by the RBEDS module 1416.

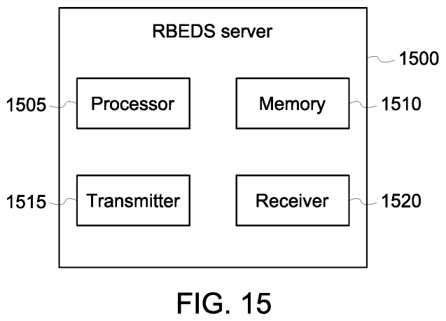

FIG. 15 illustrates an RBEDS server 1500 according to an embodiment. For example, RBEDS server 1500 may include a processor 1505, a memory 1510, a transmitter 1515, and a receiver 1520, to name just a few example components among many possibilities. For example, receiver 1520 may receive data such as PMU data, SCADA data, weather data, and other information such as DGA data and/or PD monitor data, as discussed above with respect to FIG. 8. Processor 1505 may, for example, execute program code or instructions stored in memory 1510 to process signals received by receiver 1520 to extract one or more features, generate one or more residuals, and classify the one or more residuals as one or more events and/or anomalies relating to one or more assets of or to a power grid system itself, for example. Transmitter 1515 may transmit one or more messages, such as one or more alerts, based on calculations by processor 1505. For example, if processor 1505 identifies an anomaly such as an asset or sensor which has failed or is about to fail, an alert, such as a message, may be transmitted to computing device tasked with managing operation of that asset or sensor.

As will be appreciated based on the foregoing specification, one or more aspects of the above-described examples of the disclosure may be implemented using computer programming or engineering techniques including computer software, firmware, hardware or any combination or subset thereof. Any such resulting program, having computer-readable code, may be embodied or provided within one or more non-transitory computer readable media, thereby making a computer program product, i.e., an article of manufacture, according to the discussed examples of the disclosure. For example, the non-transitory computer-readable media may be, but is not limited to, a fixed drive, diskette, optical disk, magnetic tape, flash memory, semiconductor memory such as read-only memory (ROM), and/or any transmitting/receiving medium such as the Internet, cloud storage, the internet of things, or other communication network or link. The article of manufacture containing the computer code may be made and/or used by executing the code directly from one medium, by copying the code from one medium to another medium, or by transmitting the code over a network.

The computer programs (also referred to as programs, software, software applications, “apps”, or code) may include machine instructions for a programmable processor and may be implemented in a high-level procedural and/or object-oriented programming language, and/or in assembly/machine language. As used herein, the terms “machine-readable medium” and “computer-readable medium” refer to any computer program product, apparatus, cloud storage, internet of things, and/or device (e.g., magnetic discs, optical disks, memory, programmable logic devices (PLDs)) used to provide machine instructions and/or data to a programmable processor, including a machine-readable medium that receives machine instructions as a machine-readable signal. The “machine-readable medium” and “computer-readable medium,” however, do not include transitory signals. The term “machine-readable signal” refers to any signal that may be used to provide machine instructions and/or any other kind of data to a programmable processor.

The above descriptions and illustrations of processes herein should not be considered to imply a fixed order for performing the process steps. Rather, the process steps may be performed in any order that is practicable, including simultaneous performance of at least some steps. Although the disclosure has been described in connection with specific examples, it should be understood that various changes, substitutions, and alterations apparent to those skilled in the art can be made to the disclosed embodiments without departing from the spirit and scope of the disclosure as set forth in the appended claims.

Some portions of the detailed description are presented herein in terms of algorithms or symbolic representations of operations on binary digital signals stored within a memory of a specific apparatus or special purpose computing device or platform. In the context of this particular specification, the term specific apparatus or the like includes a general-purpose computer once it is programmed to perform particular functions pursuant to instructions from program software. Algorithmic descriptions or symbolic representations are examples of techniques used by those of ordinary skill in the signal processing or related arts to convey the substance of their work to others skilled in the art. An algorithm is here, and generally, considered to be a self-consistent sequence of operations or similar signal processing leading to a desired result. In this context, operations or processing involve physical manipulation of physical quantities. Typically, although not necessarily, such quantities may take the form of electrical or magnetic signals capable of being stored, transferred, combined, compared or otherwise manipulated.

It has proven convenient at times, principally for reasons of common usage, to refer to such signals as bits, data, values, elements, symbols, characters, terms, numbers, numerals or the like. It should be understood, however, that all of these or similar terms are to be associated with appropriate physical quantities and are merely convenient labels. Unless specifically stated otherwise, as apparent from the following discussion, it is appreciated that throughout this specification discussions utilizing terms such as “processing,” “computing,” “calculating,” “determining” or the like refer to actions or processes of a specific apparatus, such as a special purpose computer or a similar special purpose electronic computing device. In the context of this specification, therefore, a special purpose computer or a similar special purpose electronic computing device is capable of manipulating or transforming signals, typically represented as physical electronic or magnetic quantities within memories, registers, or other information storage devices, transmission devices, or display devices of the special purpose computer or similar special purpose electronic computing device.

It should be understood that for ease of description, a network device (also referred to as a networking device) may be embodied and/or described in terms of a computing device. However, it should further be understood that this description should in no way be construed that claimed subject matter is limited to one embodiment, such as a computing device and/or a network device, and, instead, may be embodied as a variety of devices or combinations thereof, including, for example, one or more illustrative examples.

The terms, “and”, “or”, “and/or” and/or similar terms, as used herein, include a variety of meanings that also are expected to depend at least in part upon the particular context in which such terms are used. Typically, “or” if used to associate a list, such as A, B or C, is intended to mean A, B, and C, here used in the inclusive sense, as well as A, B or C, here used in the exclusive sense. In addition, the term “one or more” and/or similar terms is used to describe any feature, structure, and/or characteristic in the singular and/or is also used to describe a plurality and/or some other combination of features, structures and/or characteristics. Likewise, the term “based on” and/or similar terms are understood as not necessarily intending to convey an exclusive set of factors, but to allow for existence of additional factors not necessarily expressly described. Of course, for all of the foregoing, particular context of description and/or usage provides helpful guidance regarding inferences to be drawn. It should be noted that the following description merely provides one or more illustrative examples and claimed subject matter is not limited to these one or more illustrative examples; however, again, particular context of description and/or usage provides helpful guidance regarding inferences to be drawn.

While certain exemplary techniques have been described and shown herein using various methods and systems, it should be understood by those skilled in the art that various other modifications may be made, and equivalents may be substituted, without departing from claimed subject matter. Additionally, many modifications may be made to adapt a particular situation to the teachings of claimed subject matter without departing from the central concept described herein. Therefore, it is intended that claimed subject matter not be limited to the particular examples disclosed, but that such claimed subject matter may also include all implementations falling within the scope of the appended claims, and equivalents thereof.

What is claimed is:

1. A system, to monitor and diagnose a status of one or more assets of a power grid system, comprising:
a receiver to receive input measurement data and training measurement data from one or more data sources relating to the power grid system;
a processor to:
during an offline training phase,
extract first features from the training measurement data,
train one or more residual generation models using the extracted features as model inputs, and
train one or more residual-based classifiers; and
during an online monitoring and diagnosis phase,
extract second features from the input measurement data,
generate one or more residuals based on the extracted second features, the one or more residuals comprising a difference between model predicted values and measured values from the one or more data sources,
classify a status of the one or more assets based on the one or more residuals; and
generate an output indicating the status of the one or more assets based on the classification of the status.

2. The system of claim 1, wherein at least one of the input measurement data and the training measurement data comprises at least phasor measurement unit (PMU) data.

3. The system of claim 1, wherein the input data measurements further comprise one or more of Supervisory Control and Data Acquisition (SCADA) measurements, weather data, dissolved gas analysis (DGA) sensors, and/or partial discharge (PD) monitor sensors.

4. The system of claim 1, wherein at least one of the first extracted features and the second extracted features is associated with at least one of: (i) principal components, (ii) statistical features, (iii) time series analysis features, (iv) frequency domain features, (v) geographic or position based features, (vi) interaction features, (vii) logical features, (viii) deep learning features, and (ix) domain specific features.

5. The system of claim 1, wherein the extraction of at least one of the first extracted features and the second extracted features is based on calculations made over a sliding window of time-series measurements of the input measurement data.

6. The system of claim 1, wherein the one or more residual generation models are associated with at least one of: (i) a physical model, (ii) a differential equation, (iii) a density estimation-based method, (iv) an instance-based method, and (v) an auto-associative neural network model.

7. The system of claim 1, where in the one or more residual generation models are trained using a normal data set.

8. The system of claim 1, wherein the classification of the status based on the one or more residuals is based on at least one of: (i) a rule-based model, (ii) an instance-based model, (iii) a learning-based model, or a hybrid thereof.

9. The system of claim 1, wherein the processor is to further generate an alert to notify an operator based on the output.

10. The system of claim 1, wherein the output is indicative of one or more of: an instrument pre-failure, a transformer health index, an instrument drifting, a loose connection, or a breaker mis-operation.

11. A method to monitor and diagnose a status of one or more assets of a power grid system, the method comprising:
receiving input measurement data and training measurement data from one or more data sources relating to the power grid system;
during an offline training phase,
extracting first features from the training measurement data,
training one or more residual generation models using the extracted features as model inputs, and
training one or more residual-based classifiers; and
during an online monitoring and diagnosis phase,
extracting second features from the input measurement data,
generating one or more residuals based on the extracted second features, the one or more residuals comprising a difference between model predicted values and measured values from the one or more data sources,
classifying a status of the one or more assets based on the one or more residuals;
and
generating an output indicating the status of the one or more assets based on the classification of the status.

12. The method of claim 11, wherein at least one of the input measurement data and the training measurement data comprises at least phasor measurement unit (PMU) data.

13. The method of claim 11, wherein the input data measurements further comprise one or more of Supervisory Control and Data Acquisition (SCADA) measurements, weather data, dissolved gas analysis (DGA) sensors, and/or partial discharge (PD) monitor sensors.

14. The method of claim 11, wherein at least one of the first extracted features and the second extracted features is associated with at least one of: (i) principal components, (ii) statistical features, (iii) time series analysis features, (iv) frequency domain features, (v) geographic or position based features, (vi) interaction features, (vii) logical features, (viii) deep learning features, and (ix) domain specific features.

15. The method of claim 11, further comprising performing the extraction of at least one of the first extracted features and the second extracted features based on calculations made over a sliding window of time-series measurements of the input measurement data.

16. The method of claim 11, wherein the one or more residual generation models are associated with at least one of: (i) a physical model, (ii) a differential equation, (iii) a density estimation-based method, (iv) an instance-based method, and (v) an auto-associative neural network model.

17. The method of claim 11, wherein the classification of the status based on the one or more residuals is based on at least one of: (i) a rule-based model, (ii) an instance-based model, (iii) a learning-based model, or a hybrid thereof.

18. An article, comprising:
a non-transitory storage medium comprising machine-readable instructions executable by one or more processors to:
access input measurement data and training measurement data from one or more data sources relating to a power grid system;
during an offline training phase, extract first features from the training measurement data, train one or more residual generation models using the extracted features as model inputs, and train one or more residual-based classifiers; and
during an online monitoring and diagnosis phase, extract second features from the input measurement data, generate one or more residuals based on the extracted second features, the one or more residuals comprising a difference between model predicted values and measured values from the one or more data sources, and classify a status of the one or more assets based on the one or more residuals; and
generate an output indicating the status of the one or more assets based on the classification of the status.

19. The article of claim 18, wherein at least one of the input measurement data and the training measurement data comprises at least phasor measurement unit (PMU) data.

20. The article of claim 18, wherein the input data measurements further comprise one or more of Supervisory Control and Data Acquisition (SCADA) measurements, weather data, dissolved gas analysis (DGA) sensors, and/or partial discharge (PD) monitor sensors.
